(19) United States
(12) Patent Application Publication
(10) Pub. No.: US 2009/0277586 A1
(43) Pub. Date: Nov. 12, 2009

(54) Gas Introducing Apparatus, Manufacturing Method for the Gas Introducing Apparatus and Processing Apparatus

(76) Inventor: Yoshiyuki Hanada, Yamanashi-Ken (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/085,837

(22) PCT Filed: May 28, 2007
(86) PCT No.: PCT/JP2007/060777

§ 371 Date: May 30, 2008

(30) Foreign Application Priority Data
Jun. 5, 2006 (JP) 2006-156182

(51) Int. Cl. C23F 1/08; C23C 16/00; B23P 11/00

(52) U.S. Cl. 156/345.29; 118/715; 29/428

(57) ABSTRACT

The present invention provides a gas introducing apparatus, which can perform start and stop of supplying a gas at respective gas injection holes, rapidly and simultaneously. A gas introducing apparatus 24 installed in a gas-dischargeable processing vessel 22 includes a gas introducing head 110 configured to face the processing vessel. Gas supply passages 12 each configured to flow a supply gas through the gas introducing vessel, exhaust passages 114, control gas passages 116 each configured to flow a control gas, and a plurality of gas injection holes 28 provided in a face of the gas introducing head facing the processing vessel, are provided in the gas introducing head 110. Pure fluid logic elements 118 are provided in the gas introducing head 110, each being in communication with the gas supply passage, exhaust passage and control gas passage, and corresponding to each gas injection hole.

### BACKGROUND OF THE INVENTION

1. Field of the Invention

The present invention relates to a processing apparatus for providing a predetermined process to objects to be processed, such as semiconductor wafers and the like, and a gas introducing apparatus for introducing a predetermined gas into the processing apparatus and a method of manufacturing the gas introducing apparatus.

2. Background Art

Generally, in the manufacture of semiconductor integrated circuits and the like, various processes, such as film forming, etching, an oxidation diffusion process, reforming and the like, are repeatedly provided to objects to be processed, such as semiconductor wafers, in order to provide desired integrated circuits.

Upon performing such various processes, various gases are used. In the case of using such gases, for example, in a single water type processing apparatus, a structure, in which a predetermined gas is introduced into a processing vessel via a shower head provided to a ceiling portion of the processing vessel, is currently prevalent. The shower head portion includes a plurality of gas injection holes formed in a face opposed to the wafers, in order to inject a gas through the holes. Thus, a desired gas can be provided uniformly onto the surface of each wafer, thereby performing a film forming process or the like with a desired uniformity over the wafer surface.

The above process will be described with reference to FIG. 13. As shown in FIG. 13, a processing apparatus includes a processing vessel 2 formed into, for example, a cylindrical body. In the processing vessel 2, a table 6 is provided, which is raised from a bottom portion of the vessel via a post 4, and a semiconductor wafer W is placed on the table 6. In the table 6, a heating means for heating the wafer W, for example, a resistance heater 7 is provided. At the bottom portion of the processing vessel 2, an exhaust port 8 is provided, for drawing the atmosphere in the vessel to a vacuum by using a vacuum pump (not shown). At the ceiling portion of the processing vessel 2, a shower head portion 10 is provided, which is formed into a container or box-like shape having a diffusion chamber 9 of a predetermined volume defined therein. Consequently, a predetermined gas can be dispersed and supplied toward a processing space S through a plurality of gas injection holes 12 provided in a bottom face of the shower head 10.

To a gas introducing port 10A of the shower head portion 10, a gas carrier passage 12 is connected, and a predetermined gas can be supplied into the diffusion chamber 9 in the predetermined shower head portion 10 by ON/OFF of an opening and closing valve 14 attached to the gas introducing port 10A. After diffusion of the gas in the diffusion chamber 9, the gas is introduced into the processing space S through each gas injection hole 12, as described above (see. Patent Documents 1, 2, 3).

Patent Document 1: TOKUKAI No. 2002-50588, KOHO

Patent Document 2: TOKUKAI No. 2004-277772, KOHO

Patent Document 3: TOKUKAI No. 2005-64018, KOHO

The shower head 10 as described above has not attracted significant attention during the time the degrees of integration and micromachining for semiconductor integrated circuits or the like were not so critical. However, in today, when further enhanced integration and micromachining are requested, significantly higher uniformity in the surface to be processed is greatly critical. For instance, in the case of a film-forming apparatus, there is a need for enhancing the uniformity of the film thickness on the surface. Namely, in some cases, the conventional shower head 10 can not correspond sufficiently to such higher challenges as currently posed.

In order to enhance the uniformity in the surface to be processed, start and stop of supplying the gas should be done rapidly, and these operations must be performed simultaneously at the respective gas injection holes 12. Delay of gas supply, however, inevitably occurs, depending on the volume of a space provided on the downstream side relative to the opening and closing valve 14. Especially, since the diffusion chamber 9 having a predetermined volume is provided in the shower head 10, a time difference may tend to occur in the timing of starting injection or the timing of stopping injection, due to the difference of locations of the respective gas injection holes 12 formed at the central portion and at the periphery of the shower head 10.

Such a problem of delay becomes conspicuous as the diameter of the shower head 10 is increased, i.e., the distance between the central portion and the periphery of the head is increased, in particular, corresponding to enlargement of the diameter size, for example, from 200 mm to 300 mm, in the semiconductor wafer W.

Especially, among the known film forming methods, when the atomic layered deposition (ALD) method is performed, which is intended to form a desired film including multilayered thin films each having a very small thickness of an atomic or molecular level, by repeatedly supplying various kinds of film forming gases into a processing vessel with the gases changed with one another in a short time, negative impacts due to the delay as described above may tend to be conspicuous, and thus an early settlement of this problem is now demanded.

### SUMMARY OF THE INVENTION

In light of the above problems, the present invention was made to solve them. Therefore, it is an object of this invention to provide a gas introducing apparatus, a method of manufacturing the gas introducing apparatus, and a processing apparatus, in which start and stop of supplying a gas at respective gas injection holes can be performed rapidly and simultaneously.

We found that rapid and simultaneous start and stop of supplying a gas at respective gas injection holes can be achieved, by providing a pure fluid logic element to each gas injection hole, as a valve mechanism for performing start and stop of the gas supply, without employing any mechanically movable portion. Thus, the present invention was made based on the discovery.

The present invention is a gas introducing apparatus installed in a gas-dischargeable processing vessel and adapted to introduce a gas into the processing vessel, the gas introducing apparatus comprising: a gas introducing head configured to face the processing vessel; gas supply passages each configured to flow a supply gas through the gas introducing head; exhaust passages each provided in the gas introducing head; control gas passages each configured to flow a control gas through the gas introducing head; a plurality of gas injection holes provided in a face of the gas introducing head facing the processing vessel; and pure fluid logic elements each provided in communication with the gas supply passage, exhaust passage and control gas passage, corresponding to each gas injection hole.

By providing the pure fluid logic element for each gas injection hole as a valve mechanism for performing start and stop of supplying a gas, rapid and simultaneous start and stop of supplying the gas can be achieved at the respective gas injection holes, without employing any mechanically movable portion. Of course, it is also possible to provide a construction which can perform the same function as said above, even by employing any other fluid logic elements including mechanically movable portions (including pneumatic valves) or other suitable opening and closing mechanisms. In such a case, however, the structure becomes significantly complicated, and the risk of generating particles associated with movement of such mechanically movable portions is likely to occur, thus deteriorating the reliability. Therefore, it is a key point of this invention to employ the pure fluid logic element as describe above.

The present invention is the gas introducing apparatus described above, wherein each pure fluid logic element includes: a main communication passage communicating the gas supply passage with the gas injection hole and having a bending portion bent at a predetermined angle in the middle portion of the main communication passage; a branched communication passage branched at a predetermined angle from the bending portion and communicated with each exhaust passage; and a control communication passage communicating the control gas passage with the bending portion.

The present invention is the gas introducing apparatus described above, wherein each control gas passage includes an ON control gas passage for flowing an ON control gas and an OFF control gas passage for flowing an OFF control gas, and wherein a control communication passage extending from the ON control gas passage and a control communication passage extending from the OFF control gas passage are connected with the bending portion of each pure fluid logic element such that these control communication passages will face each other to form a bi-stable type pure fluid logic element.

The present invention is the gas introducing apparatus described above, wherein each control gas passage is composed of a single passage, and wherein the control communication passage extending from the control gas passage with the bending portion of each pure fluid logic element to form a mono-stable type pure fluid logic element.

The present invention is the gas introducing apparatus described above, wherein the gas supply passages, exhaust passages and control gas passages are provided, respectively corresponding to the number of kinds of gases to be supplied.

The present invention is the gas introducing apparatus described above, wherein the gas introducing head is provided at a ceiling portion of the processing vessel, and the supply gas passages, exhaust passages and control gas passages are arranged in parallel to one another when viewed in a plane defined by the ceiling portion.

The present invention is the gas introducing apparatus described above, wherein the gas introducing head is provided at one side wall in the processing vessel.

The present invention is the gas introducing apparatus described above, wherein the plurality of gas injection holes are arranged in a plurality of groups of zones, such that the gas injection holes can be controlled independently in each zone.

The present invention is the gas introducing apparatus described above, wherein a buffer chamber is provided in the middle portion of each main communication passage between each gas injection hole and the bending portion.

The present invention is a manufacturing method for a gas introducing apparatus, which is installed in a gas-dischargeable processing vessel and adapted to introduce a gas into the processing vessel, wherein the gas introducing apparatus includes: a gas introducing head configured to face the processing vessel; gas supply passages each configured to flow a supply gas through the gas introducing head; exhaust passages each provided in the gas introducing head; control gas passages each configured to flow a control gas through the gas introducing head; a plurality of gas injection holes provided in a face of the gas introducing head facing the processing vessel; and pure fluid logic elements each provided in communication with the gas supply passage, exhaust passage and control gas passage, corresponding to each gas injection hole, the manufacturing method comprising the steps of: forming a plurality of blocks for constituting the gas introducing head; and joining the blocks to one another to assembly them together, thus forming the gas introducing head.

The present invention is the manufacturing method described above for a gas introducing apparatus, wherein each of the blocks is formed to have a rectangular parallelepiped shape; and wherein through-holes are formed in each block, respectively corresponding to the gas supply passages, exhaust passages and control passages, and grooves are formed in a surface of each block, respectively corresponding to each communication passage for forming each pure fluid logic element.

The present invention is a processing apparatus comprising: a processing vessel adapted to discharge a gas; and a gas introducing apparatus installed in the processing vessel and configured to introduce the gas into the processing vessel, wherein the gas introducing apparatus includes: a gas introducing head configured to face the processing vessel; gas supply passages each configured to flow a supply gas through the gas introducing head; exhaust passages each provided in the gas introducing head; control gas passages each configured to flow a control gas through the gas introducing head; a plurality of gas injection holes provided in a face of the gas introducing head facing the processing vessel; and pure fluid logic elements each provided in communication with the gas supply passage, exhaust passage and control gas passage, corresponding to each gas injection hole.

The present invention is the processing apparatus described above, wherein each pure fluid logic element includes: a main communication passage communicating the gas supply passage with the gas injection holes and having a bending portion bent at a predetermined angle in the middle portion of the main communication passage; a branched communication passage branched at a predetermined angle from the bending portion and communicated with the exhaust passage; and a control communication passage communicating the control gas passage with the bending portion.

The present invention is the processing apparatus described above, wherein the control gas passage includes an ON control gas passage for flowing an ON control gas and an OFF control gas passage for flowing an OFF control gas, and wherein a control communication passage extending from the ON control gas passage and a control communication passage extending from the OFF control gas passage are connected with the bending portion of each pure fluid logic element such that these control communication passages will face each other to form a bi-stable type pure fluid logic element.

The present invention is the processing apparatus described above, wherein the control gas passage is composed of a single passage, and wherein the control communication passage extending from the control gas passage with the bending portion of each pure fluid logic element to form a mono-stable type pure fluid logic element.

The present invention is the processing apparatus described above, wherein the gas supply passages, exhaust passages and control gas passages are provided, respectively corresponding to the number of kinds of gases to be supplied.

The present invention is the processing apparatus described above, wherein the gas introducing head is provided at a ceiling portion of the processing vessel, and the supply gas passages, exhaust passages and control gas passages are arranged in parallel to one another when viewed in a plane defined by the ceiling portion.

The present invention is the processing apparatus described above, wherein the gas introducing head is provided at one side wall in the processing vessel.

The present invention is the processing apparatus described above, wherein the plurality of gas injection holes are arranged in a plurality of groups of zones, such that the gas injection holes can be controlled independently in each zone.

The present invention is the processing apparatus described above, wherein a buffer chamber is provided in the middle portion of each main communication passage between each gas injection hole and the bending portion.

According to the gas introducing apparatus, the manufacturing method thereof and the processing apparatus, related to the present invention, the following effect can be obtained.

Namely, rapid and simultaneous start and stop of supplying the gases at the respective gas injection holes can be achieved, by providing the pure fluid logic element to each gas injection hole as a valve mechanism for performing start and stop of the gas supply, without employing any mechanically movable portion.

### BRIEF DESCRIPTION OF THE DRAWINGS

FIG. 1 is a view showing a processing apparatus employing a gas introducing apparatus according to the present invention.

FIG. 2 is a view showing a gas injection face of the gas introducing apparatus.

FIG. 3 is a partially enlarged view showing a gas introducing head of a first embodiment of the gas introducing apparatus.

FIG. 4(A) is a cross sectional view taken along line a-a of FIG. 3, FIG. 4(B) is a cross sectional view taken along line b-b of FIG. 3, and FIG. 4(C) is a cross sectional view taken along line c-c of FIG. 3.

FIG. 5(A) is a side view showing one example of a manufacturing method for the gas introducing apparatus, and FIG. 5(B) is a perspective view of the gas introducing apparatus.

FIGS. 6 (A), 6(B) and 6(C) are views, respectively illustrating the operational principle of a pure fluid logic element.

FIGS. 7(A) and 7(B) are views, respectively illustrating the operational principle of the gas introducing apparatus employing the pure fluid logic element.

FIG. 8 is a timing chart showing one example of introducing modes of an A gas and a B gas.

FIG. 9 is an enlarged cross sectional view showing a second embodiment of the gas introducing apparatus of the present invention.

FIG. 10 is a view showing a third embodiment of the gas introducing apparatus of the present invention.

FIG. 11 is an enlarged cross sectional view showing a fourth embodiment of the gas introducing apparatus of the present invention.

FIG. 12 is a timing chart showing one example of introducing modes of an A gas and a B gas.

FIG. 13 is a schematic view showing one example of a conventional processing apparatus.

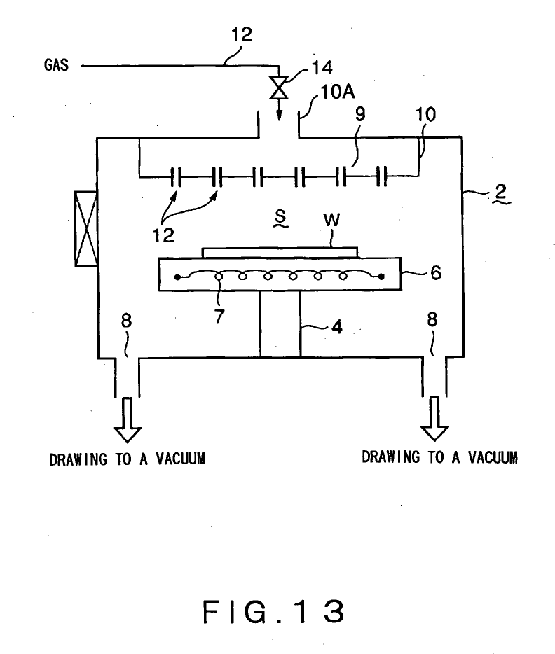

### DETAILED DESCRIPTION OF THE INVENTION

Hereinafter, one embodiment of a gas introducing apparatus according to the present invention, a manufacturing method and a processing apparatus for the gas introducing apparatus will be discussed, in detail, based on attached drawings.

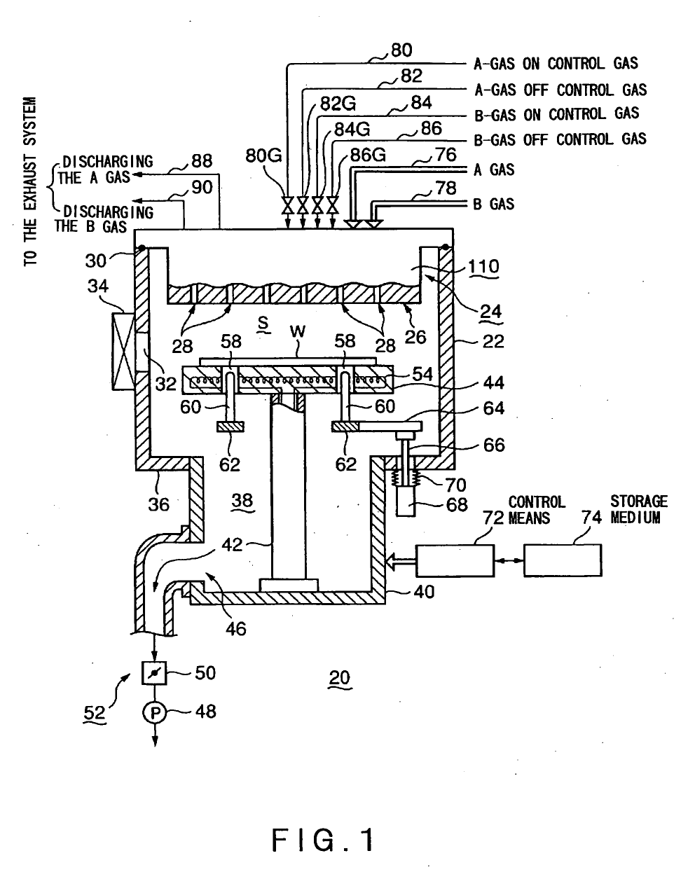

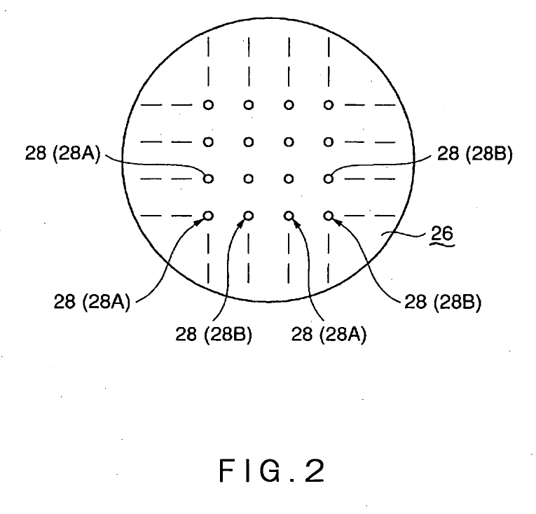

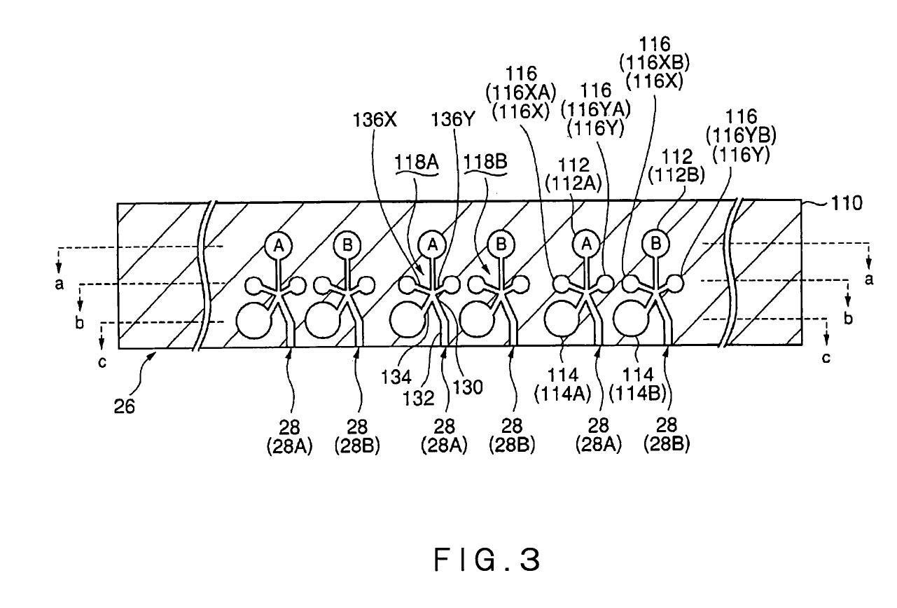

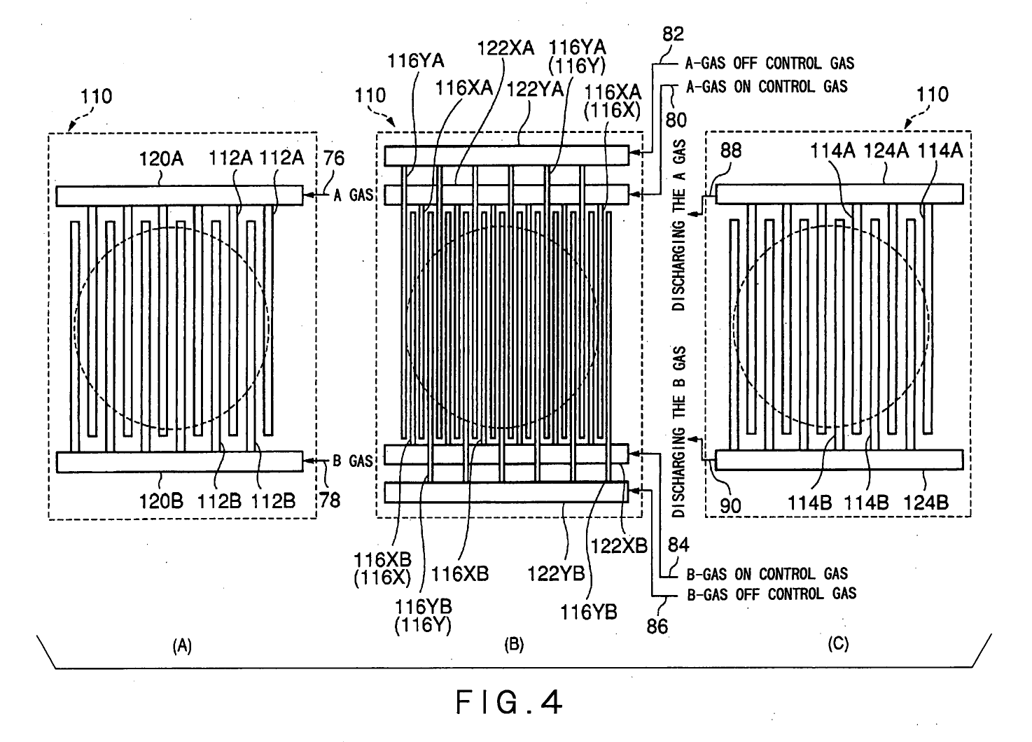

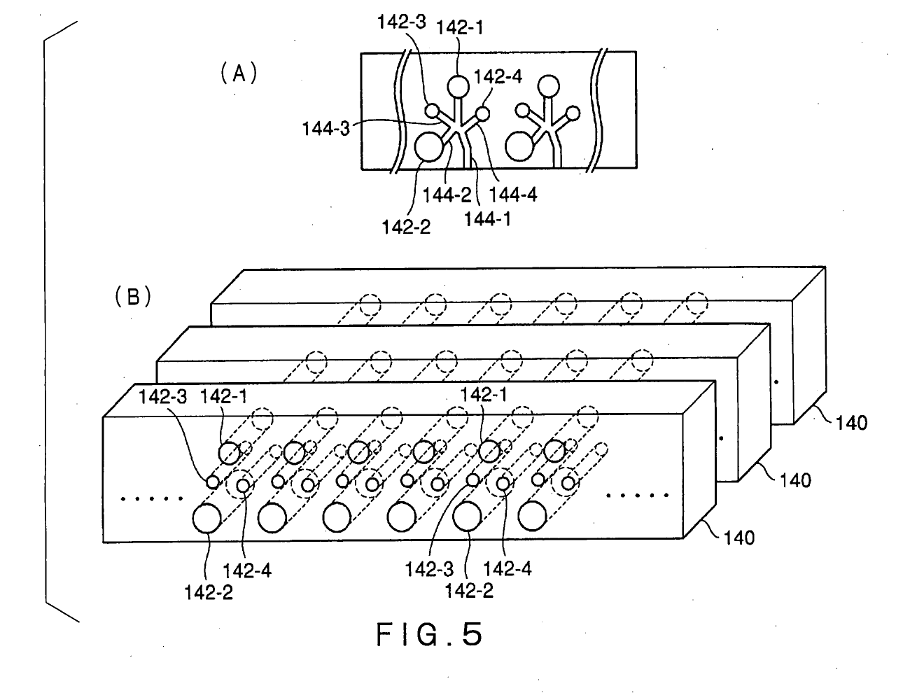

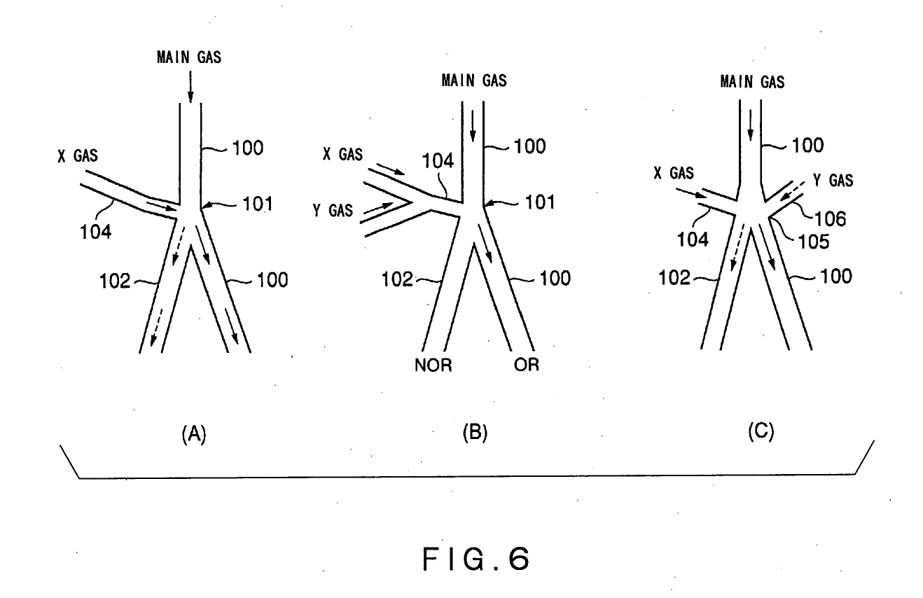

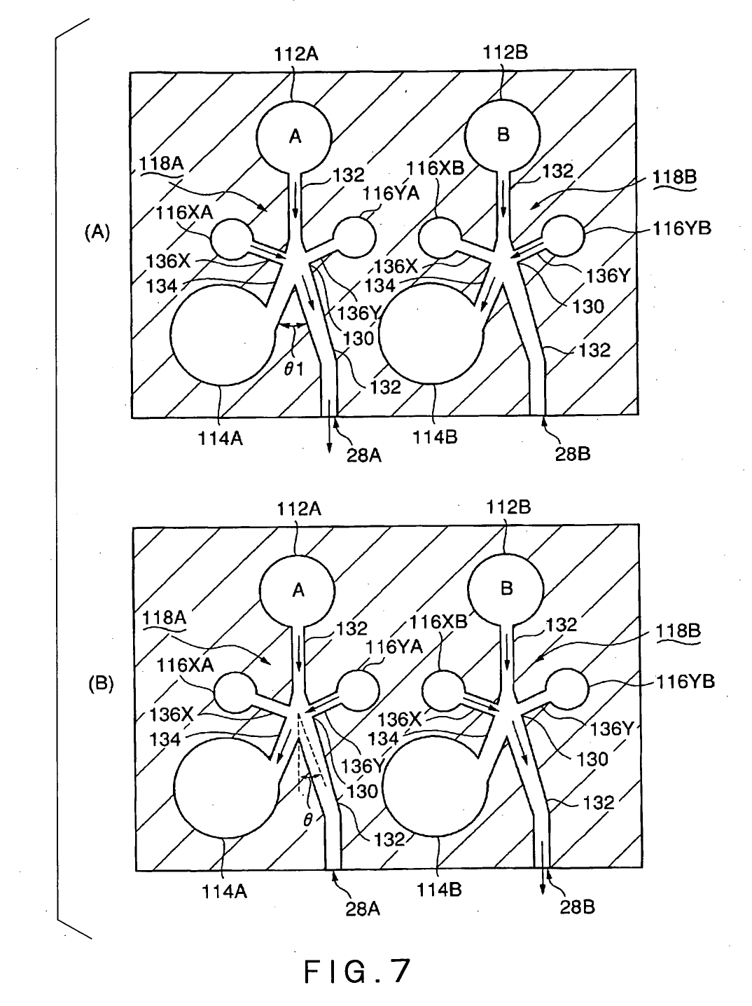

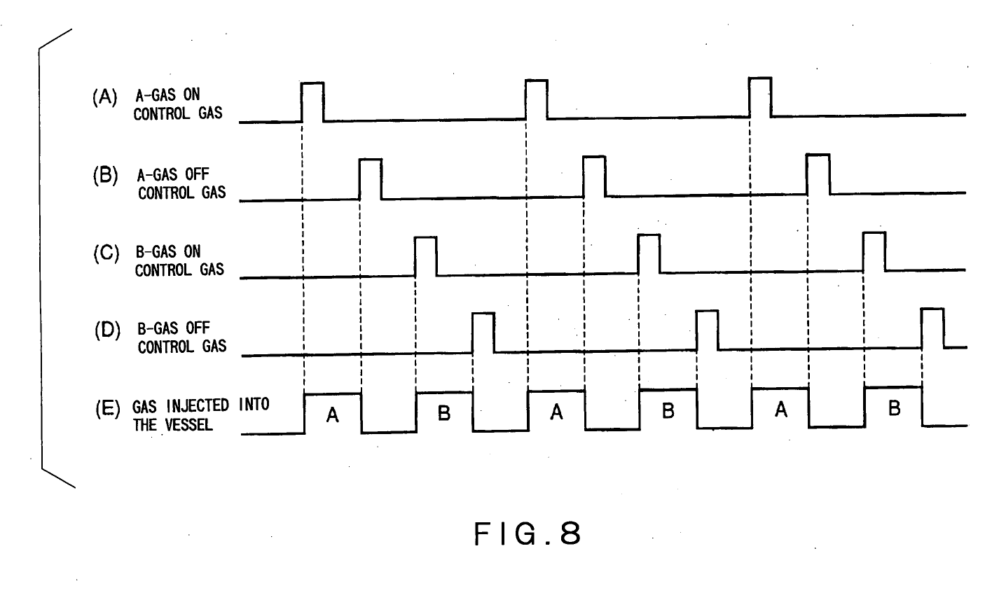

FIG. 1 is a view showing a processing apparatus employing a gas introducing apparatus according to the present invention, FIG. 2 is a diagram showing a gas injection face of the gas introducing apparatus, FIG. 3 is a partially enlarged view showing a gas introducing head of a first embodiment of the gas introducing apparatus. FIGS. 4(A), 4(B), 4(C) are cross sections respectively taken along lines a-a, b-b, c-c of FIG. 3. FIGS. 5(A) and 5(B) are diagrams showing one example of a manufacturing method for the gas introducing apparatus, FIGS. 6 (A), 6(B) and 6(C) are views, respectively illustrating the operational principle of a pure fluid logic element. FIGS. 7(A) and 7(B) are views, respectively illustrating the operational principle of a gas introducing apparatus employing a pure fluid logic element, and FIG. 8 is a timing chart showing one example of introducing modes of an A gas and a B gas.

As shown in the drawings, a processing apparatus 20 includes a processing vessel 22 which has, for example, a generally cylindrical shape, defining a processing space S, and is made of aluminum, and a gas introducing apparatus 24 provided to a ceiling portion of the processing vessel 22 and adapted to introduce a processing gas required. A plurality of gas injection holes 28 are provided in a gas injection face 26 of the gas introducing apparatus 24, such that the processing gas is blown out from the gas injection holes 28 toward the processing space S. As shown in FIG. 2, the gas injection holes 28 are provided in a fashion of, for example, a matrix, arranged both in longitudinal and transverse directions, in the gas injection face 26.

The gas introducing apparatus 24 will be detailed below. At a junction of the gas introducing apparatus 24 and a top opening end of the processing vessel 22, a sealing member 30, composed of, for example, an O ring, is provided in order to keep air tightness in the processing vessel 22.

In a side wall of the processing vessel 22, a transfer port 32 is provided for carrying a semiconductor wafer W, as an object to be processed, in and out to the processing vessel 22. A gate valve 34 is provided to the transfer port 32 that can be opened and closed airtightly.

A lower exhaust space 38 communicates with a bottom portion 36 of the processing vessel 22. Specifically, a large opening is formed in a central portion of the bottom portion 36 of the vessel, and a cylindrical partition wall 40 having a bottom wall extending downward is connected with the opening of the bottom portion 36, so as to form the lower exhaust space 38. A cylindrical post 42 is provided extending upward from the bottom wall of the cylindrical partition wall 40, and a table 44 is fixed to a top end of the post 42. The wafer W is placed and held (supported) on the table 44.

The processing gas flows downward aside the table 44 travels below the table 44, and then flows into the space 38. An exhaust port 46 is formed in a lower portion of a side wall of the cylindrical partition wall 40, while facing the lower exhaust space 38. A vacuum pump 48 and a pressure control valve 50, constituting together an exhaust system 52, are connected with the exhaust port 46 of the cylindrical partition wall 40. Thus, the atmosphere both in the processing vessel 22 and the lower exhaust space 38 can be discharged through the exhaust system 52.

In addition, the table 44 includes a heating means, for example, a resistance heater 54, provided, in a desired pattern, in the interior of the table 44, and the outside of the table 44 is formed of a sintered material, for example, an ALN ceramic or the like. As the heating means, a heating lump may be employed in place of the resistance heater 54.

In the table 44, a plurality of, for example, three, pin insertion holes 58 are provided to extend vertically through the table 44 (only two of the holes are depicted in FIG. 1). Through each pin insertion holes 58, a push-up pin 60 is inserted movably in the vertical direction in a freely fitted state. At a bottom end of each push-up pin 60, a push-up ring 62 formed of a ceramic, for example, alumina, is placed, and the push-up ring 62 has a circular arc shape, i.e., a partly cut-off circular ring. The bottom end of each push-up pin 60 is supported on a top face of the push-up ring 62. Additionally, an arm 64 extending from each push-up ring 62 is connected with a vertically movable rod 66 extending through the bottom portion 36 of the processing vessel 24. The rod 66 is configured to move vertically due to an actuator 68.

Thus, each push-up pin 60 can be moved upward from a top end of each pin insertion hole 58 when transferring the wafer W. Around an insertion portion of the actuator 68 for each vertically movable rod 66 at the bottom end of the processing vessel 24, an extendable bellows 70 is fitted, so that the vertically movable rod 66 can be moved in the vertical direction while keeping air-tightness in the processing vessel 22.

Furthermore, a control means 72 comprising, for example, a microcomputer, is provided for controlling various conditions, such as the entire operation of the processing apparatus 20, start of supply and stop of supply of various gases, wafer temperature, processing pressure, and the like. The control means 72 includes a storage medium 74 for storing a program for performing the above control, and the storage medium 74 is composed of, for example, a flexible disk, a hard disk, a flash memory or the like.

### [Pure Fluid Logic Element]

Now, prior to explanation about the gas introducing apparatus 24, the principle of the pure fluid logic element will be described, in brief, with reference to FIG. 6.

The pure fluid logic element is described in more detail in, for example, “Fluid logic Element”, Bulletin of Japan Physical Academic Society, Vol. 23, No. 6 (June, 1968), pp. 553(59)-558(64) or TOKUKAISHO No. 55-119294, KOHO.

The pure fluid logic element is configured to control the direction of a jet stream by utilizing a phenomenon (Coanda effect or Wall effect) that a jet stream, such as a gas or the like, flows along a surface of a material. Specifically, when assuming pressure or flow of a gas to be a signal, a unit body, in which the relation between a flowing-in signal (input signal) and a flowing-out signal (output signal) can be connected with a logic, can be considered as a pure fluid logic element.

For example, as shown in FIG. 6(A), assume that a bending portion 101 having a predetermined angle is provided in an intermediate portion of a pipe 100 for flowing a main gas therein, and that a branched pipe 102 is connected at the bending portion 101. In addition, a control gas pipe 104 for introducing a control gas is further connected with the bending portion 101. Depending on the angle of the bending portion 101 and/or on the offset amount of the pipe 100 or the like, it is decided whether the main gas having flowed through the pipe 100 will further flow along a side wall of the pipe 100 after passing through the bending portion 101, or it will depart from the pipe 100 and then approach to and flow along a side wall of the branched pipe 102.

In this case, when the control gas is not introduced into the pipe, the main gas having flowed through the pipe 100 will depart from the pipe 100 and then flow through the branched pipe 102, after passing through the bending portion 101. In such a situation, when the control gas (X gas) is introduced through the control gas pipe 104, the flow of the main gas is changed from the branched pipe 102 into the pipe 100. However, when the introduction of the control gas is stopped in this situation, the flow of the main gas is changed again into the branched pipe 102. Such an element is referred to as a mono-stable type.

The shape of the bending portion 101 shown in FIG. 6(B) is also the mono-stable type similar to that shown in FIG. 6(A), in which two kinds of gases, i.e., an X gas and a Y gas, can be introduced separately through the control gas pipe 104. In this case, when either one or both of the X gas and Y gas are introduced through the pipe 104, the flow of the main gas is changed into the pipe 100. However, when the introduction of the X gas and/or Y gas is stopped, the flow of the main gas is changed into the branched pipe 102. Accordingly, when assuming the X gas and Y gas to be an input signal, the pipe 100 can be considered as an “OR” output, while the branched pipe 102 can be considered as a “NOR” output.

In an example shown in FIG. 6(C), the offset amount at a bending portion 105 for each of the pipes 100 and 102 is set to be equal. Another control gas pipe 106 is provided at the bending portion 105, such that the control gas pipe 106 is arranged to be symmetrical, together with the control gas pipe 104, with respect to the center line. The Y gas can be supplied through the control gas pipe 106.

The bending portion 105 is configured such that each gas can selectively approach to and stably flow along both of the side wall of the pipe 100 and the side wall of the branched pipe 102, both extending downstream relative to the bending portion 105. Such a bending portion 105 is referred to as a bi-stable type. Namely, when the X gas is supplied in a pulse state, the flow of the main gas is changed into the pipe 100 and still flows through the pipe 100. On the other hand, when the Y gas is supplied in a pulse-like fashion, the flow of the main gas is changed into the branched pipe 102 and continues to flow in that state. Such a phenomenon is similar to the flip-flop element. Thus, by utilizing such a phenomenon, an element or device, having a function similar to a logic element, such as an AND element, OR element, NOR element, NAND element or the like, for use in an electronic circuit element, i.e., the pure fluid logic element, can be constructed as needed.

### EXAMPLES

### First Embodiment

### Gas Introducing Apparatus

Based on the principle of the pure fluid logic element described above, a first embodiment of the gas introducing apparatus 24 will be detailed with reference to FIGS. 3 to 5. In the first embodiment, a flip-flop type pure fluid logic element as shown in FIG. 7(C) is employed. In the drawing, different kinds of two gases, for example, an A gas and a B gas are supplied into the processing vessel 22.

As shown in FIG. 1, the gas introducing apparatus 24 is provided at a ceiling portion of the processing vessel 22 and has a shower head structure. To the gas introducing apparatus 24, an A gas line 76 for supplying the A gas, a B gas line 78 for supplying the B gas, an A-gas ON control gas line 80 for flowing an A-gas ON control gas, an A-gas OFF control gas line 82 for flowing an A-gas OFF control gas, a B-gas ON control gas line 84 for flowing a B-gas ON control gas, a B-gas OFF control gas line 86 for flowing a B-gas OFF control gas, an A gas exhaust line 88 for discharging the A gas, and a B gas exhaust line 90 for discharging the B gas, are connected, respectively.

Both of the exhaust lines 88, 90 for the A gas and B gas are connected with the exhaust system 52 and, for example, drawn to a vacuum successively upon performing a process. At intermediate portions of the respective control gas lines 80 to 86 for the A-gas ON control, A-gas OFF control, B-gas ON control and B-gas OFF control, opening and closing valves 80G, 82G, 84G, 86G are respectively provided for controlling ON/OFF of the respective gases, thereby to achieve individual ON/OFF control for each gas. In order to reduce the volume of the passage on the downstream side of each opening and closing valve 80G to 86G, these valves are provided possibly near to the gas introducing apparatus 24. As the control gas described above, an inert gas, for example, argon (Ar) gas, can be employed.

The A gas and B gas are respectively supplied such that the flow rate of each gas is controlled by a flow rate controller, such as a mass flow controller (not shown). The gas introducing apparatus 24 includes a gas introducing head 110 provided to face the processing space S and having a predetermined thickness. In the gas introducing head 110, gas supply passages 112 for flowing respective gases are provided. Exhaust passages 114 are also provided in the gas introducing head 110. In addition, control gas passages 116 for flowing respective control gases are provided in the gas introducing head 110. Corresponding to the respective gas injection holes 28, pure fluid logic elements 118 are provided for communicating the plurality of gas injection holes 28, gas supply passages 112, exhaust passages 114, and control gas passages 116, with one another. The gas introducing head 110 is formed from a resin, for example, a fluorinated resin, or a metal, for example, an aluminum alloy or nickel alloy.

Specifically, since the two kinds of gases, i.e., the A gas and B gas, are introduced in this example, each gas passage is provided for each gas to be supplied. As shown in FIG. 4(A), the gas supply passages 112A for the A gas and the gas supply passages 112B for the B gas are respectively arranged, alternately, in a large number, along the horizontal direction, in upper positions in the thickness direction, of the gas introducing head 110. One end of each gas supply passage 112A for the A gas is connected commonly to an A gas header 120A, and the A gas line 76 is also connected with the A gas header 120A. In such a construction, the A gas is supplied to the A gas header 120A.

One end of each gas supply passage 112B for the B gas is connected commonly to a B gas header 120B located in a position on the opposite side relative to the A gas header 120A, and the B gas line 78 is also connected with the B gas header 120B. In such a construction, the B gas is supplied to the B gas header 120B.

As shown in FIG. 4(B), the control gas passages 116 include ON control gas lines 116X and OFF control gas lines 116Y for each pure fluid logic element 118. Among these gas lines, A-gas ON gas passages 116XA and A-gas OFF passages 116YA are provided, in parallel, along the control gas passages 116, in intermediate positions in the thickness direction, of the gas introducing head 110. One end of each ON gas passage 116XA for the A gas is connected commonly to an A-gas ON header 122XA, while one end of each OFF gas passage 116YA for the A gas is connected commonly to an A-gas OFF header 122YA. The A-gas ON line 80 is also connected with the A-gas ON header 122XA, while the A-gas OFF line 82 is also connected with the A-gas OFF header 122YA. Thus, the control gases can be selectively supplied, respectively.

As described above, and as shown in FIG. 4(B), the control gas passages 116 include ON control gas lines 116X and OFF control gas lines 116Y for each pure fluid logic element 118. Among these gas lines, B-gas ON gas passages 116XB and B-gas OFF passages 116YB are provided, in parallel, along the control gas passages 116, in intermediate positions in the thickness direction, of the gas introducing head 110. One end of each ON gas passage 116XB for the B gas is connected commonly to a B-gas ON header 122XB in a position located on the opposite side relative to the A-gas ON header 122XA, while one end of each OFF-gas passage 116YB for the B gas is connected commonly to a B-gas OFF header 122YB. The B-gas ON line 84 is also connected with the B-gas ON header 122XB, while the B-gas OFF line 86 is also connected with the B-gas OFF header 122YB. Thus, the control gases can be selectively supplied, respectively.

As shown in FIG. 4(C), exhaust gas passages 114A for the A gas and exhaust gas passages for the B gas are respectively arranged, alternately, in a large number, along the horizontal direction, in lower positions in the thickness direction, of the gas introducing head 110. One end of each exhaust gas passage 114A for the A gas is connected commonly to an A gas header 124A, and the A gas exhaust line 88 is also connected with the A gas header 124A. Thus, the A gas can be discharged into the A gas header 124A.

One end of each exhaust gas passage 114B for the B gas is connected commonly to a B gas header 124B, and the B gas exhaust line 90 is also connected with the B gas header 124B. Thus, the B gas can be discharged into the B gas header 124B.

The pure fluid logic elements 118 are provided, such that pure fluid logic elements 118A for the A gas and pure fluid logic elements 118B for the B gas are arranged alternately, as shown in FIG. 3. Since these two kinds of pure fluid logic elements have the same structure, only the pure fluid logic element 118A will be detailed by way of example.

Each pure fluid logic element 118A is a flip-flop type element which has been described above, with reference to FIG. 6(C). Specifically, as shown in FIGS. 3 and 7, each pure fluid logic element 118A comprises: a main communication passage 132 communicating the gas supply passage 112A for the A gas with the gas injection hole 28A and having a bending portion 130, which is provided at an intermediate portion and bent defining a predetermined angle θ; a branched communication passage 134 branched at the bending portion 130, defining a predetermined angle θ1 relative to the main communication passage 132, and communicated with the exhaust passage 114A for the A gas; and control communication passages 136X, 136Y, respectively provided by communicating the bending portion 130 with the control gas passages 116XA, 116YB, for the A-gas ON and A-gas OFF.

Since the pure fluid logic element 118A is operated similarly to the flip-flop type element as shown in FIG. 6(C), when the control gas for A-gas ON is flowed in a pulse state from the side of one control communication passage 136X, the A gas flowing in the main communication passage 132 from the gas supply passage 112A will pass through the bending portion 130 and still flow through the main communication passage 132, as such it is introduced into the processing vessel 22 via the gas injection hole 28A for the A gas. On the other hand, when the control gas for A-gas OFF is flowed in a pulse state from the side of the other control communication passage 136Y, the flow of the A gas will be changed into the branched communication passage 134 at the bending portion 130, and the A gas is then discharged from the exhaust passage 114A. This operation is the same in all of the pure fluid logic elements 118A, 118B. Therefore, the A gas and B gas can be selectively introduced into the processing vessel 22.

It is also possible to provide a construction which can perform the same function as said above, even by employing any other fluid logic elements including mechanically movable portions (including pneumatic valves) or other suitable opening and closing mechanisms. In such a case, however, the structure becomes significantly complicated, and the risk of producing particles associated with movement of such mechanically movable portions is likely to occur, thus deteriorating the reliability. Therefore, it is a key point of this invention to employ the pure fluid logic element as describe above.

### [Manufacturing Method]

One example of a manufacturing method for the gas introducing head 110 will be described with reference to FIG. 5. As shown in FIG. 5, a plurality of blocks 140, each having a rectangular parallelepiped shape and a predetermined thickness, are formed with a material for forming the gas introducing head 110. For instance, the thickness of each block 140 is approximately 10 mm. In order to form the respective gas supply passages 112, respective exhaust passages 114 and respective control gas passages 116 in each block 140, through-holes 142-1 to 142-4 are formed to extend in the thickness direction of each block 140, respectively corresponding to portions for these passages. Additionally, in the surface on one or both sides of each block 140, grooves 144-1 to 144-4 are formed to have respectively predetermined thicknesses, corresponding to the respective communication passages, i.e., the main communication passages 132, branched communication passages 134 and control communication passages 136X, 136Y, for forming the respective pure fluid logic elements 118.

Once forming each block 140 in this manner, the so-formed blocks 140 are integrally joined to one another by welding or the like means, with the respective through-holes 142-1 to 142-4 and respective grooves 144-1 to 144-4 being aligned with one another, thereby to form the gas introducing head 110. In this case, the grooves 144-1 to 144-4 and/or through-holes 142-1 to 142-4 may be formed by etching for achieving micromachining, or otherwise they may be formed by injection molding or casting, by using an appropriate mold. It should be appreciated that the manufacturing method described herein is by way of example only, and that it is not limited to the above aspects.

Next, the operation of the processing apparatus constructed as described above will be discussed with reference to FIGS. 7 and 8. In this case, one example of building up layered thin films by using the so-called ALD method will be described, in which an A gas and a B gas, as the film forming gases, are supplied repeatedly and alternately.

Prior to the carrying in operation of the semiconductor wafer W, the atmosphere in the processing vessel 22 of the processing apparatus 20, which is connected with, for example, a load-lock chamber (not shown), is drawn to a vacuum. The table 44 for placing the wafer W thereon is heated to a predetermined temperature and maintained in a stable state, due to the resistance heater 54 used as the heating means.

In this state, the unprocessed semiconductor wafer W having, for example, a 300 mm diameter, is carried into the processing vessel 22, via the gate valve 34 and transfer port 32 which are respectively opened, while the wafer W is held by a carrying arm (not shown). After transferred onto the raised push-up pins 60, the wafer W is placed on the top face of the table 44, by lowering the push-up pins 60.

Subsequently, while supplying various gases into the gas introducing apparatus 24 comprising the shower head, alternately and repeatedly, as will be described below, the atmosphere in the processing vessel 22 and lower exhaust space 38 is drawn to a vacuum, by continuing actuation of the vacuum pump 48 provided in the exhaust system 52. As such, the atmosphere in the processing space S is maintained to be a predetermined processing pressure, by adjusting the degree of opening the pressure control valve. Thus, predetermined thin films are respectively formed on the surface of the semiconductor wafer W.

Hereinafter, an aspect of supplying each gas will be described specifically.

Prior to the start of the film forming process, the A gas and B gas are flowed stably at predetermined flow rates, respectively. The A gas is supplied into the respective gas supply passages 112A for the A gas, via the A gas line 76 and A gas header 120A (see FIG. 4). By supplying the control gas for the A-gas OFF in a pulse state, such that the A gas flows down through the main communication passage 132 of each pure fluid logic element 118A for the A gas and then flows toward the branched passage 134 via the bending portion 130, the A gas will flow through the branched passage 134, thus finally the A gas can be discharged to the outside of the system from each exhaust passage 114A for the A gas. Accordingly, in this state, the A gas is not supplied into the processing vessel 22. This state is stable and depicted as the pure fluid logic element 118A shown on the left side in FIG. 7(B).

The B gas is supplied into the respective gas supply passages 112B for the B gas, via the B gas line 78 and B gas header 120B (see FIG. 4). By supplying the control gas for the B-gas OFF in a pulse state, such that the B gas flows down through the main communication passage 132 of each pure fluid logic element 118B for the B gas and then flows toward the branched passage 134 via the bending portion 130, the B gas will flow through the branched passage 134, thus finally the B gas can be discharged to the outside of the system from each exhaust passage 114B for the B gas. Accordingly, in this state, the B gas is not supplied into the processing vessel 22. This state is stable and depicted as the pure fluid logic element 118B shown on the right side in FIG. 7(A).

In the state described above, as shown in FIG. 8, the A gas and B gas are introduced into the processing vessel 22, alternately and repeatedly, thus providing a film forming process. In the drawing, FIG. 8(A) shows the control gas for the A-gas ON, FIG. 8(B) shows the control gas for the A-gas OFF, FIG. 8(C) shows the control gas for the B-gas ON, FIG. 8(D) shows the control gas for the B-gas OFF, and FIG. 8(E) shows the kinds of gases to be introduced into the processing vessel 22.

In order to introduce the A gas into the reaction vessel 22, the control gas is flowed, as depicted on the left side in FIG. 7(A), in a pulse state, through the control gas passage 116XA for the A-gas ON, in each pure fluid logic element 118A for the A gas (see FIG. 8(A)). Consequently, based on the principle of the flip-flop element, the direction of the flow of the A gas is changed from that toward the exhaust passage 114A for the A gas into the direction toward the downstream of the main communication passage 132 depicted on the right side in the drawing relative to the exhaust passage 114A. As a result, the A gas will be introduced into the processing vessel 22 from each gas injection hole 28A for the A gas. This state will be maintained stably until the control gas for the A-gas OFF is supplied subsequently in a pulse state.

In order to stop the introduction of the A gas into the processing vessel 22, the control gas is flowed, as depicted on the left side in FIG. 7(B), in a pulse state, through the control gas passage 116YA for the A-gas OFF (see FIG. 8(B)). Again, based on the principle of the flip-flop element, the direction of the flow of the A gas is changed from that toward the downstream of the main communication passage 132 into the stream toward the exhaust passage 114A, for the A gas, depicted on the left side relative to the main communication passage 132. As a result, the A gas will be discharged into the exhaust system 52, thus will not be introduced into the processing vessel 22. This state will be maintained stably until the control gas for the A-gas ON is supplied subsequently in a pulse state.

In this state, no gas is supplied into the processing vessel 22, and remaining gases in the processing vessel 22 are discharged.

In order to perform the start and stop of supplying the B gas, the same operations, described above for each pure fluid logic element 118A for the A gas, are carried out for each pure fluid logic element 118B for the B gas. Namely, in order to introduce the B gas into the processing vessel 22, the control gas is flowed, as depicted on the right side in FIG. 7(B), in a pulse state, through the control gas passage 116XB for the B-gas ON, in each pure fluid logic element 118B for the B gas (see FIG. 8(C)). Consequently, based on the principle of the flip-flop element, the direction of the flow of the B gas is changed from that toward the exhaust passage 114B for the B gas into the direction toward the downstream of the main communication passage 132 depicted on the right side in the drawing relative to the exhaust passage 114B in the drawing. As a result, the B gas will be introduced into the processing vessel 22 from each gas injection hole 28B for the B gas. This state will be maintained stably until the control gas for the B-gas OFF is supplied subsequently in a pulse state.

In order to stop the introduction of the B gas into the processing vessel 22, the control gas is flowed, as depicted on the left side in FIG. 7(B), in a pulse state, through the control gas passage 116YB for the B-gas OFF (see FIG. 8(D)). Again, based on the principle of the flip-flop element, the direction of the flow of the B gas is changed from that toward the downstream of the main communication passage 132 into the stream toward the exhaust passage 114B, for the B gas, depicted on the left side in the drawing relative to the main communication passage 132. As a result, the B gas will be discharged into the exhaust system 52, thus will not be introduced into the processing vessel 22.

This state will be maintained stably until the control gas for the B-gas ON is supplied subsequently in a pulse state. In this state, no gas is supplied into the processing vessel 22, and remaining gases in the processing vessel 22 are discharged.

By repeating the series of operations described above, the A gas and B gas can be supplied, alternately and repeatedly, into the processing vessel 22, with a predetermined interval, thereby to perform the film forming process due to the ALD method.

As stated above, while the conventional shower head structure could not correspond to rapid changing of gases because of the volume of the shower head itself, the present invention can perform start and stop of supplying the gas, rapidly and simultaneously, for each gas injection hole 28, without employing any mechanically movable portion, only by providing the pure fluid logic element, for each gas injection hole, as a valve mechanism for starting and stopping the gas supply.

In addition, according to this invention, since the space required for piping located on the downstream side relative to the opening and closing valves 80G, 82G, 84G, 86G provided in the respective control gas lines 80, 82, 84, 86 and the volume in the shower head can be minimized, more rapid gas changing can be achieved.

### Second Embodiment

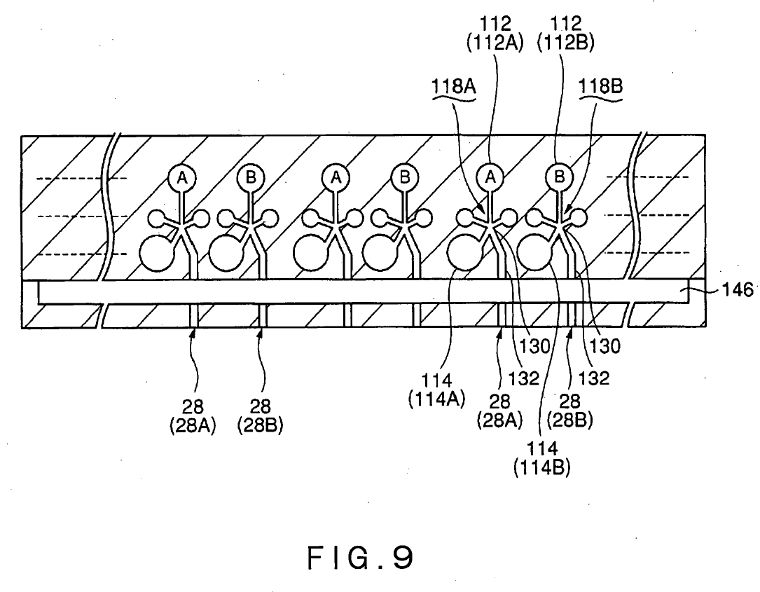

Next, a second embodiment of the present invention will be described. Generally, the pure fluid logic element 118 employed in this invention can not be used under a pressure condition out of the viscous flow region (for example, the region higher than 50 Torr). Accordingly, when the processing pressure in the processing vessel 22 is about 1 Torr (or 133 Pa), which is out of the above viscous flow region, a buffer chamber is provided in the middle of the main communication passage immediately above each gas injection hole 28. FIG. 9 is an enlarged cross section showing a second embodiment of the gas introducing apparatus of the present invention. As shown in the drawing, a buffer chamber 146 having a small volume extending commonly in a planar direction is provided in the middle of each main communication passage 132 between each gas injection hole 22 and each bending portion 130.

In this way, by providing the buffer chamber 146, even when the processing pressure in the processing space S is lower than the viscous flow region, the A gas and B gas can first flow into the buffer chamber 146, and each gas can then be supplied into the processing space S through the gas injection holes 28. In this case, while lowering of response to the ON/OFF operation for each gas to be introduced can not be avoided, optimum conditions can be selected by controlling the balance between the pressure to be used and the response to be required.

### Third Embodiment

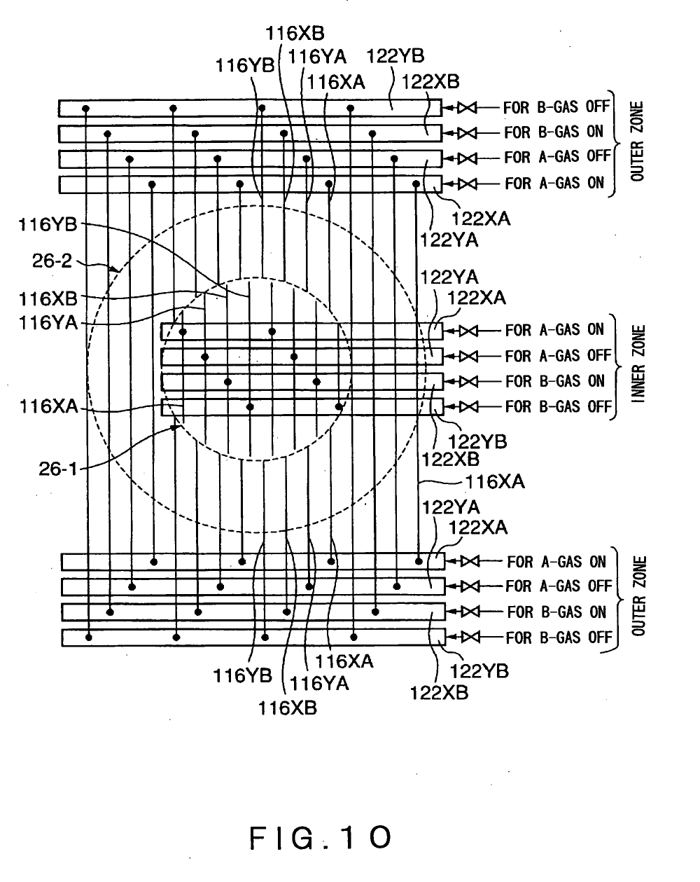

Next, a third embodiment of this invention will be described. While, in the previous embodiments, the example, in which the A gas and B gas are respectively controlled in a single zone, has been described, the control manner is not limited to this aspect. For instance, the respective gas injection holes may be divided into a plurality of zones so as to control each gas for each zone independently. FIG. 10 shows the third embodiment of the gas introducing apparatus of the present invention, in which one example of arrangement of the control gas passages is illustrated.

As shown in FIG. 10, the gas injection face 26 is divided into two concentric circular zones, i.e., an inner zone 26-1 and an outer zone 26-2. In this configuration, the respective gas injection holes (not shown) are also divided into groups, corresponding to the inner zone and the outer zone.

For the necessity of individually controlling the ON/OFF operation for each zone, the control gas passages and the gas headers connected thereto are provided individually for each zone. Namely, in a central portion depicted in the drawing, the A-gas ON header 122XA, the A-gas OFF header 122YA, the B-gas ON header 122XB, the B-gas OFF header 122YB, for the inner zone, are provided, respectively.

In addition, in an upper portion and a lower portion depicted in the drawing, the A-gas ON headers 122XA, the A-gas OFF headers 122YA, the B-gas ON headers 122XB, the B-gas OFF headers 122YB, for the outer zones, are provided, respectively.

In this case, the control gas passages 116X, 116Y are divided and disconnected, at the boundary of the inner zone and the outer zone, to form sections in the respective zones, and are respectively connected with the ON headers and OFF headers arranged in the two upper and lower portions depicted in the drawing. In the regions out of the inner zone, however, each control gas passage connected with the corresponding upper and lower headers depicted in the drawing may be fully connected. It should be appreciated that each control gas passage can be provided in a grade separation manner at a point where the passage crosses each header.

With such configuration, the respective gas injection holes 28 can be divided into a plurality of zones, for example, the inner zone and the outer zone, as such start and stop of supplying the A gas and B gas can be controlled, corresponding to each zone.

In this embodiment, the gas supply passages 112A, 112B for the A gas and B gas and the exhaust passages 114A, 114B for the A gas and B gas are formed in the same manner as those in the first embodiment.

It should be noted that the number of zones to be divided is not limited to two, but may be three or more, and that the shape of each zone is not limited to the concentric circle.

### Fourth Embodiment

Next, a fourth embodiment of this invention will be described. While, in the previous embodiments, an example, in which the flip-flop bi-stable type element is used as the pure fluid logic element 118, has been described, it is not limited to this aspect, but the mono-stable type element can also be employed (see FIG. 6(A)).

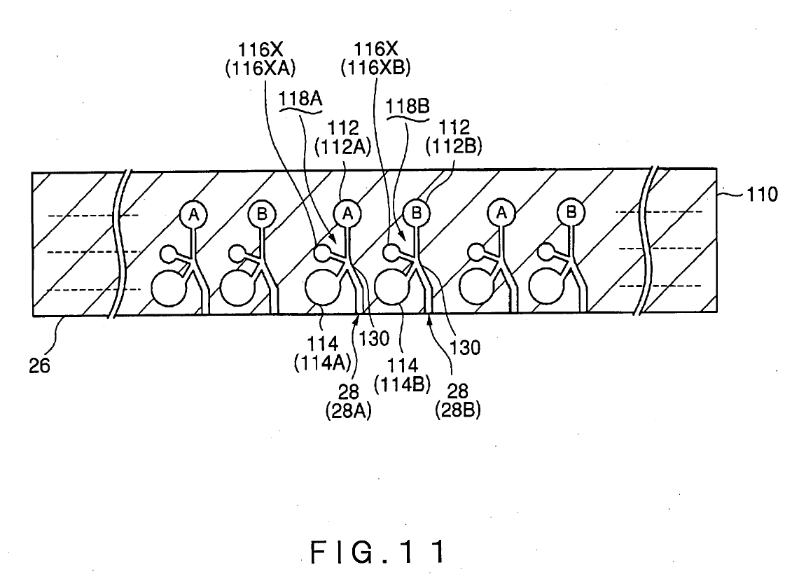

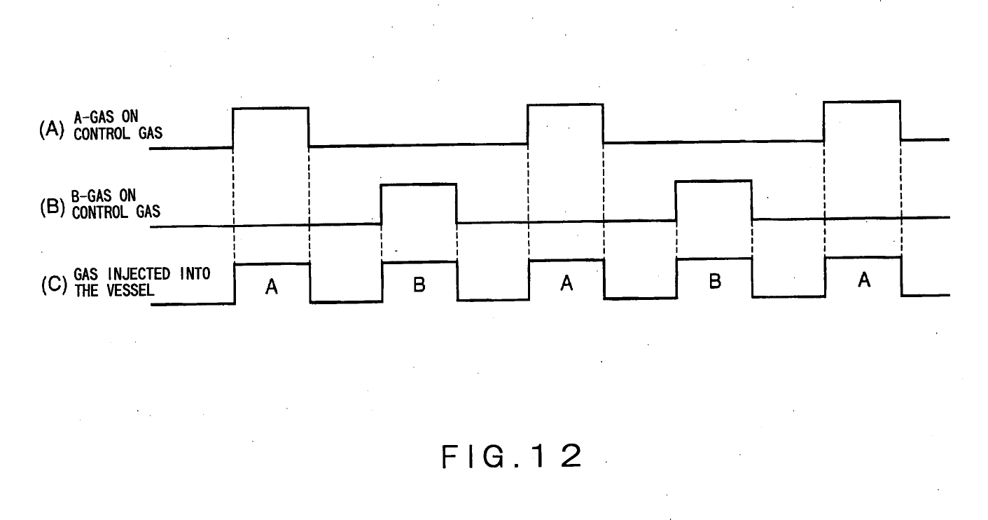

FIG. 11 is an enlarged cross section showing the fourth embodiment of the gas introducing apparatus of the present invention, and FIG. 12 is a timing chart showing one example of introducing modes for the A gas and B gas. In the drawings, like reference numerals are assigned to like parts shown in FIG. 3. In the fourth embodiment, since each fluid logic element 118A, 118B is of the mono-stable type, the OFF control gas passages 116A, 116B for the A gas and B gas and the respective control communication passages 136Y used in the embodiment shown in FIG. 3 are not required.

In this case, however, at the bending portion 130 of each pure fluid logic element 118A, 118B, the offset amount or the like is set, such that the A gas and B gas can be flowed into the exhaust passages 114A, 114B, respectively, in a stable state.

In the case of using such mono-stable type pure fluid logic elements 118A, 118B, as shown in FIG. 12, the A gas will be introduced into the processing space S, during a period of time the A-gas ON control gas is kept in the ON state, while the B gas will be introduced into the processing space S, during a period of time the B-gas ON control gas is maintained in the ON state.

While, in the embodiments described above, the case, in which the film-forming process is performed by using the ALD method by way of example, has been discussed, the film-forming process utilizing the CVD method may also be employed. The present invention is not limited to the film forming process, but may also be applied to various kinds of apparatuses for performing etching, an oxidation diffusion process, reforming and the like.

Furthermore, the apparatus described above may also be used as a plasma processing apparatus, by forming the gas introducing head 110 with a metallic material and applying high frequency power for generating plasma to the gas introducing head 110, or by applying high frequency biasing power to the wafer table.

While each embodiment described above has been discussed with respect to the use of the two kinds of gases, the A gas and B gas, the present invention can also be applied to the case of using three kinds or more of gases. Of course, at least one of the three or more kinds of gases may be used as a purging gas (Ar, N₂, H₂, etc.).

While the Ar gas is used as the control gas, it is not limited to this aspect. Namely, other inert gases, such as N₂ gas, He gas, Ne gas or the like, may also be used.

While, in the above embodiments, the case, in which the gas introducing apparatus 24 is provided in a form of the shower head structure located at the ceiling portion of the processing vessel 22, has been described, it is not limited to this aspect. For instance, the present invention can also be applied to the so-called side-flow type processing apparatus, in which the processing vessel is formed into a rectangular shape and the gas introducing apparatus 24 is provided at one side wall, while each gas to be used is discharged from the other side wall.

Although only the three kinds of examples are illustrated in FIG. 6 as the logic forms for the pure fluid logic element, the logic form is not limited to these aspects. Namely, it is also possible to create a function to produce an output in accordance with a logical function formed by combining basic logics, such as AND/OR/NOT/NAND/XOR, in response to an input signal. Additionally, by utilizing such a function, it is also possible to establish further complicated operations for individual elements and/or a group of elements. In this case, it is necessary to construct an operational circuit using each pure fluid logic element. Therefore, while the structure will be complicated to some extent, various merits can be obtained as described below.

(1) It is possible to perform the A-gas ON operation and the B-gas OFF operation (by using a NOT element) at the same time, by using, for example, an A-gas ON command. Thus, an ON/OFF command circuit (passage) for the B gas can be omitted.

(2) The operation to turn the purging gas ON only when both of the A gas and B gas are OFF can be executed by using a NOR element. Thus, an ON command circuit (passage) for the purging gas can be omitted.

(3) The use of the T-type flip-flop circuit can change the ON/OFF states, alternately, for each input of the command signal pulse.

(4) The use of the RS-type flip-flop circuit can achieve self holding of the gas ON/OFF states. Therefore, the command signal can also be used as a pulse without holding it.

(5) The use of a simple delay circuit can delay only the operational timing of a particular element relative to the ON/OFF timing for the command gas, intentionally, by a predetermined period of time. Consequently, the gas ON/OFF timing can be shifted in a certain position in a plane, or otherwise the ON/OFF timing for only one of different kinds of gases can be shifted relative to the command signal. However, the degree of freedom of the process is decreased because the delaying time and/or the element to be delayed is fixed, in advance, depending on the mechanical structure.

(6) By combining the delay circuit with either one of the T-type flip-flop circuit or RS-type flip-flop circuit (i.e., by connecting the output of the flip-flop circuit to an input port through the delaying circuit), the ON/OFF operation can be automatically continued, without providing frequent ON/OFF operations to the original command signal. Due to the setting of the delay circuit, a higher speed operation of the millisecond order can be realized, theoretically, thus achieving very high speed gas changing control in the vicinity of the wafer, as needed.

(7) Adding to those described above, various other logic functions can be applied by utilizing a variety of combinations of the pure fluid logic elements.

Finally, while the object to be processed has been explained herein with respect to the semiconductor wafer by way of example, it is not limited to this aspect. For instance, the present invention can also be applied to glass substrates, LCD substrates, ceramic substrates or the like.

1. A gas introducing apparatus installed in a gas-dischargeable processing vessel and adapted to introduce a gas into the processing vessel, the gas introducing apparatus comprising:
a gas introducing head configured to face the processing vessel;
gas supply passages each configured to flow a supply gas through the gas introducing head;
exhaust passages each provided in the gas introducing head;
control gas passages each configured to flow a control gas through the gas introducing head;
a plurality of gas injection holes provided in a face of the gas introducing head facing the processing vessel; and
pure fluid logic elements each provided in communication with the gas supply passage, exhaust passage and control gas passage, corresponding to each gas injection hole.

2. The gas introducing apparatus according to claim 1, wherein each pure fluid logic element includes:
a main communication passage communicating the gas supply passage with the gas injection hole and having a bending portion bent at a predetermined angle in the middle portion of the main communication passage;
a branched communication passage branched at a predetermined angle from the bending portion and communicated with each exhaust passage; and
a control communication passage communicating the control gas passage with the bending portion.

3. The gas introducing apparatus according to claim 2,
wherein each control gas passage includes an ON control gas passage for flowing an ON control gas and an OFF control gas passage for flowing an OFF control gas, and
wherein a control communication passage extending from the ON control gas passage and a the control communication passage extending from the OFF control gas passage are connected with the bending portion of each pure fluid logic element such that these control communication passages will face each other to form a bi-stable type pure fluid logic element.

4. The gas introducing apparatus according to claim 2,
wherein each control gas passage is composed of a single passage, and
wherein the control communication passage extending from the control gas passage is connected with the bending portion of each pure fluid logic element to form a mono-stable type pure fluid logic element.

5. The gas introducing apparatus according to claim 1,
wherein the gas supply passages, exhaust passages and control gas passages are provided, respectively corresponding to the number of kinds of gases to be supplied.

6. The gas introducing apparatus according to claim 1,
wherein the gas introducing head is provided at a ceiling portion of the processing vessel, and the supply gas passages, exhaust passages and control gas passages are arranged in parallel to one another when viewed in a plane defined by the ceiling portion.

7. The gas introducing apparatus according to claim 1,
wherein the gas introducing head is provided at one side wall in the processing vessel.

8. The gas introducing apparatus according to claim 1,
wherein the plurality of gas injection holes are arranged in a plurality of groups of zones, such that the gas injection holes can be controlled independently in each zone.

9. The gas introducing apparatus according to claim 2,
wherein a buffer chamber is provided in the middle portion of each main communication passage between each gas injection hole and the bending portion.

10. A manufacturing method for a gas introducing apparatus, which is installed in a gas-dischargeable processing vessel and adapted to introduce a gas into the processing vessel,
wherein the gas introducing apparatus includes:
a gas introducing head configured to face the processing vessel;
gas supply passages each configured to flow a supply gas through the gas introducing head;
exhaust passages each provided in the gas introducing head;
control gas passage each configured to flow a control gas through the gas introducing head;
a plurality of gas injection holes provided in a face of the gas introducing head facing the processing vessel; and
pure fluid logic elements each provided in communication with the gas supply passage, exhaust passage and control gas passage, corresponding to each gas injection hole, the manufacturing method comprising the steps of:
forming a plurality of blocks for constituting the gas introducing head; and
joining the blocks to one another to assembly them together, thus forming the gas introducing head.

11. The manufacturing method for a gas introducing apparatus according to claim 10,
wherein each of the blocks is formed to have a rectangular parallelepiped shape; and
wherein through-holes are formed in each block, respectively corresponding to the gas supply passages, exhaust passages and control passages, and grooves are formed in a surface of each block, respectively corresponding to each communication passage for forming each pure fluid logic element.

12. A processing apparatus comprising:
a processing vessel adapted to discharge a gas; and
a gas introducing apparatus installed in the processing vessel and configured to introduce the gas into the processing vessel,
wherein the gas introducing apparatus includes:
a gas introducing head configured to face the processing vessel;
gas supply passages each configured to flow a supply gas through the gas introducing head;
exhaust passages each provided in the gas introducing head;
control gas passages each configured to flow a control gas through the gas introducing head;
a plurality of gas injection holes provided in a face of the gas introducing head facing the processing vessel; and
pure fluid logic elements each provided in communication with the gas supply passage, exhaust passage and control gas passage, corresponding to each gas injection hole.

13. The processing apparatus according to claim 12,
wherein each pure fluid logic element includes:
a main communication passage communicating the gas supply passage with the gas injection holes and having a bending portion bent at a predetermined angle in the middle portion of the main communication passage;
a branched communication passage branched at a predetermined angle from the bending portion and communicated with the exhaust passage; and
a control communication passage communicating the control gas passage with the bending portion.

14. The processing apparatus according to claim 13,
wherein the control gas passage includes an ON control gas passage for flowing an ON control gas and an OFF control gas passage for flowing an OFF control gas, and
wherein a control communication passage extending from the ON control gas passage and a control communication passage extending from the OFF control gas passage are connected with the bending portion of each pure fluid logic element such that these control communication passages will face each other to form a bi-stable type pure fluid logic element.

15. The processing apparatus according to claim 13,
wherein the control gas passage is composed of a single passage, and
wherein the control communication passage extending from the control gas passage with the bending portion of each pure fluid logic element to form a mono-stable type pure fluid logic element.

16. The processing apparatus according to claim 12,
wherein the gas supply passages, exhaust passages and control gas passages are provided, respectively corresponding to the number of kinds of gases to be supplied.

17. The processing apparatus according to claim 12,
wherein the gas introducing head is provided at a ceiling portion of the processing vessel, and the supply gas passages, exhaust passages and control gas passages are arranged in parallel to one another when viewed in a plane defined by the ceiling portion.

18. The processing apparatus according to claim 12,
wherein the gas introducing head is provided at one side wall in the processing vessel.

19. The processing apparatus according to claim 12,
wherein the plurality of gas injection holes are arranged in a plurality of groups of zones, such that the gas injection holes can be controlled independently in each zone.

20. The processing apparatus according to claim 13,
wherein a buffer chamber is provided in the middle portion of each main communication passage between each gas injection hole and the bending portion.
